(19) United States
(12) Patent Application Publication
(10) Pub. No.: US 2005/0133736 A1
(43) Pub. Date: Jun. 23, 2005

(54) Ion implantation apparatus and partical collection structure thereof

(76) Inventors: Otto Chen, Tainan County (TW); Yao-Chia Yeh, HsinChu City (TW); Chun-Feng Shen, Tainan City (TW); Chung-Tung Chen, Taoyuan County (TW)

Correspondence Address: BIRCH STEWART KOLASCH & BIRCH, PO BOX 747, FALLS CHURCH, VA, 22040-0747, US

(21) Appl. No.: 10/736,757

(22) Filed: Dec. 17, 2003

(51) Int. Cl. H01J 37/317

(52) U.S. Cl. 250/492.21

(57) ABSTRACT

An ion implantation apparatus. An ion implantation chamber has a movable work piece support holding one or more work pieces and a connecting housing between the ion implantation chamber and an accelerator thereof. A plurality of collectors with saw-toothed protrusions are mounted on the interior surface of the ion implantation chamber and the housing, and grounded to fix contaminant particles moving within the ion implantation apparatus.

### BACKGROUND OF THE INVENTION

1. Field of the Invention

The present invention concerns a method for capturing and removing contaminant particles from an ion implanter and, more particularly, contaminant particles captured by securing a particle collector having an adhering surface in fluid communication with the interior region of the implanter.

2. Description of the Related Art

Ion implanters are used to implant or “dope” silicon wafers with impurities to produce n or p type extrinsic materials. The n and p type extrinsic materials are utilized in the production of semiconductor integrated circuits. As its name implies, the ion implanter dopes the silicon wafers with a selected ion species to produce the desired extrinsic material. Implanting ions generated from source materials such as antimony, arsenic or phosphorus results in n type extrinsic material wafers. If p type extrinsic material wafers are desired, ions generated with source materials such as boron, gallium or indium will be implanted.

The ion implanter includes an ion source for generating positively charged ions from ionizable source materials. The generated ions are formed into a beam and accelerated along a predetermined beam path to an implantation station. The ion implanter includes beam forming and shaping structure extending between the ion source and the implantation station, maintaining the ion beam and bounding an elongated interior cavity or region through which the beam passes en route to the implantation station. During implantion, the interior region must be evacuated to reduce the probability of ions being deflected from the predetermined beam path as a result of collisions with air molecules.

For high current ion implanters, the wafers at the implantation station are mounted on a surface of a rotating support. As the support rotates, the wafers pass through the ion beam. Ions traveling along the beam path collide with and are implanted into the rotating wafers. A robotic arm withdraws wafers to be treated from a wafer cassette and positions the wafers on the wafer support surface. After treatment, the robotic arm removes the wafers from the wafer support surface and redeposits the treated wafers in the wafer cassette.

Operation of an ion implanter results in the production of certain contaminant particles. One source of contaminant particles is undesirable ion species generated by the ion source. Contaminant particles with respect to a given implant result from the presence of residual ions from a previous implant in which different ions were implanted. For example, after implanting boron ions in a given number of wafers, it may be desired to change over the implanter to implant arsenic ions. It is likely that some residual boron atoms will remain in the interior region of the implanter.

Yet another source of contaminant particles is photoresist material. Photoresist material is coated on wafer surfaces prior to implantation and is required to define circuitry on the completed integrated circuit. As ions strike the wafer surface, particles of photoresist coating are dislodged therefrom.

Contaminant particles colliding with and adhering to wafers during ion treatment are a major source of yield loss in the fabrication of semiconductor and other devices which require submicroscopic pattern definition on the treated wafers.

In addition to rendering the implanted or treated wafers unsuitable for their intended purpose in the manufacture of integrated circuits, contaminant particles adhering to interior surfaces of the ion implanter reduce the efficiency of ion implanter components. For example, the performance of an ion beam neutralization apparatus can be detrimentally affected by a buildup of photoresist particles on the apparatus' aluminum extension tube.

The vacuum environment of the implanter interior complicates capture and removal of contaminant particles. In a vacuum, the motion of submicroscopic particles is extremely difficult to control, and particle movement is controlled largely by electrostatic forces. Gravitational forces become insignificant with decreasing particle size.

It has been found that particles moving within the evacuated interior of the implanter bounce or rebound repeatedly before settling on and adhering to the work piece surface or to an interior surface of the implanter. Experience indicates that such a moving particle may bounce 10 to 25 times before settling.

In essence, a particle collector includes a particle adhering surface. Particles colliding with the surface become attached thereto and are removed when the collector is removed. However, for a particle collector to be used in conjunction with an ion implanter, the particle collector must be compatible with the vacuum environment. Conventional particle collector surfaces, such as adhesives, porous materials, and oily materials, tend to outgas in a vacuum environment, which makes them inappropriate for use. What is needed is a particle collector for contaminant particles suitable for use in a vacuum environment and exhibiting high particle adhering qualities.

U.S. Pat. No. 5,656,092 to Blake et at. teaches an ion implanter with a particle collector of aluminum foam plates for trapping contaminant particles in the interior region of the implanter traversed by an ion beam. However, aluminum foam plates are more expensive, and plates with foams coarser than 10 pores per inch, despite a better removing efficiency, are harder to fabricate. Furthermore, although the aluminum foam plate has irregular depressions on the surface, the photoresist particles dislodged from wafers will also adhere to the surface of the aluminum foam plates, forming an insulation layer thereon, decreasing the efficiency of the ion beam neutralization apparatus. Thus, there is a need to provide an ion implanter having improved particle collection capabilities suitable for use in a vacuum environment.

### SUMMARY OF THE INVENTION

Accordingly, the first object of the invention is to provide an improved particle collection structure in an ion implanter.

Another object of the invention is to provide a particle collector for ion beam neutralization apparatus preventing efficiency drop from photoresist particle adhesion.

The present invention provides an ion implantation apparatus with contaminant particle collectors. The ion implantation apparatus has an ion source, a mass-analysis magnet, an accelerator and an ion implantation chamber. The mass-analysis magnet mass-analyzes an ion beam extracted from the ion source. The accelerator accelerates or decelerates and directs the ion beam to a work piece fixed in the ion implantation chamber. Furthermore, a plurality of first collectors are removably disposed on an interior surface of the ion implantation chamber, each having a first surface with a plurality of parallel saw-toothed first protrusions, to fix contaminant particles in the ion implantation chamber.

The ion implantation apparatus also has a Faraday cup, disposed behind the work piece support in the emission direction of the ion beam, measuring the current of the ion beam. The first collectors are grounded and mounted on the interior surface of the ion implantation chamber with the first surface facing the Faraday cup.

The ion implantation apparatus has a connecting housing between the accelerator and the ion implantation chamber, comprising an ion beam neutralization element and a plurality of second collectors, removably mounted on the interior surface thereof. Each second collector has a second surface with a plurality of parallel saw-toothed second protrusions to fix the contaminant particles in the housing. The second collectors are grounded, forming a bias voltage with the ion beam neutralization element.

The first and second protrusions are right triangular with a top included angle between 45 and 70°, and are graphite.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic view showing an ion implantation apparatus of the present invention;

FIG. 2 is a schematic view showing the Faraday cup and the first collectors mounted on the interior surface of the ion implantation chamber.

FIG. 3 is a schematic view showing the second collectors disposed in the connecting housing to capture particles moving through the interior region of the ion implantation apparatus.

### DETAILED DESCRIPTION OF THE INVENTION

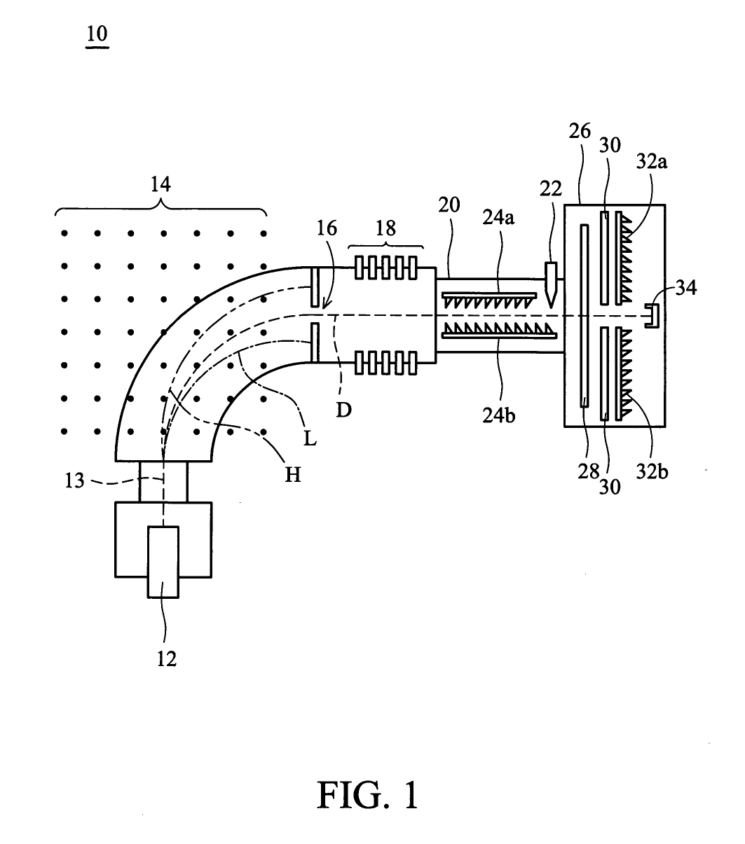

FIG. 1 shows an ion implantation apparatus 10 including an ion source 12 generating positively charged ions from ionizable source materials. The generated ions are extracted from the ion source 12, forming an ion beam 13, and injected into a mass-analysis magnet 14. In this region, ions of different mass in the ion beam 13 are mass-analyzed and deflected in different paths by magnetic force, such that desired ion species (D) in the ion beam 13 are easily selected by a mass-analyzing slit 16, and the ions (H and L) with larger or smaller mass than desired ion species (D) are filtered out.

In FIG. 1, the desired ions (D) are guided into an accelerator 18 after passing through the mass-analyzing slit 16. The accelerator 18 includes a plurality of acceleration electrodes connected in series to accelerate or decelerate the desired ions (D) along a predetermined beam path to an ion implantation chamber 26. The ion implantation chamber 26 includes a disk shaped wafer support 28. Wafers to be treated are positioned near the peripheral edge of the wafer support 28 and the support is rotated by a motor (not shown) at about 1200 RPM, moving one or more wafers through the ion beam (D). The ion beam (D) impinges on the wafers, treating them as they rotate in a circular path.

The ion implantation apparatus 10 of the invention has a Faraday cup 34 disposed in the ion implantation chamber 26, directly behind the wafer support 28 in the emission direction of the ion beam (D). Because of a slit (not shown) positioned at the peripheral edge between two disk holding positions on the wafer support 28, the ion beam (D) passes through the slit, impinging on the Faraday cup 34 as the support rotates. Thus, the real time current of the ion beam (D) can be measured.

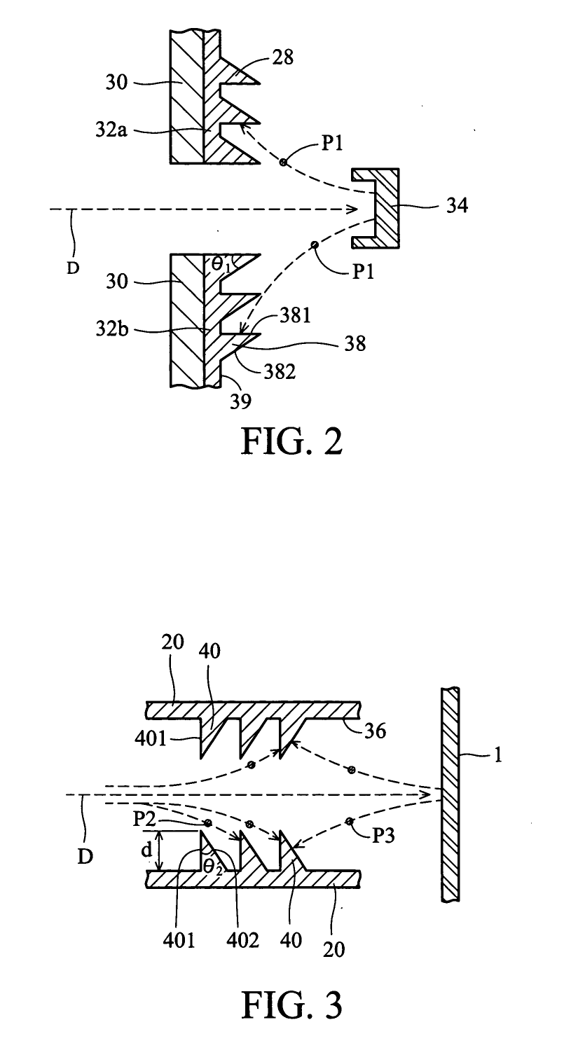

In FIGS. 1 and 2, because the Faraday cup 34 is graphite and continuously bombarded by ions (D), graphite particles (P1) are produced and tends to be ejected from the Faraday cup 34. The ion implantation apparatus 10 of the invention thus has a plurality of first collectors 32a, 32b removably mounted to the partitions 45 of the ion implantation chamber 26 to reduce the number of moving particles therein. Each of the first collectors 32a, 32b has a first surface 39 with a plurality of parallel saw-toothed first protrusions 38. In FIG. 2, each first protrusion 32a, 32b has a first toothed surface 381 and a second toothed surface 382 with a first included angle θ₁. The first toothed surface of each first protrusion is perpendicular to the first surface 39 of each first collector 32a, 32b. The first collectors 32a, 32b are graphite and grounded, to stop or fix ejected positive-charged graphite particles and reduce bouncing stray particle contamination.

In FIG. 1, the ion implantation apparatus 10 of the inventions further has a connecting housing 20 between the accelerator 18 and the ion implantation chamber 26. In order to reduce beam blow-up, the connecting housing 20 has an ion beam neutralization element 22, such as an electron gun, and a plurality of particle collectors 24a, 24b removably mounted on an interior surface thereof. The second collectors 24a, 24b are graphite and grounded, forming a bias voltage in the connecting housing 20 with the ion beam neutralization element 22. Thus, the ion beam (D) passing through the interior region thereof is neutralized by secondary electron emissions.

In FIG. 3, each second collector has a second surface 36 with a plurality of parallel saw-toothed second protrusions 40 to fix stray contaminant particles (P2, P3) in the connecting housing 20. Each second protrusion 40 of the second collectors 24a, 24b has a third toothed surface 401 and a fourth toothed surface 402 with a second included angle 02. The third toothed surface 401 of each second protrusion 40 is perpendicular to the second surface 36 of each second collector 24a, 24b. The second collectors 24a, 24b fix stray contamination particles P2 in the interior region of the connecting housing and positive-charged photoresist particles P3 ejected from the treated wafer 1 by electrostatic force. Furthermore, after a number of wafers are treated, an insulation film forms on the fourth toothed surface 402 of each second protrusion 40. The third toothed surface 401 and the recessed portion therebetween, however, is not covered by photoresist particles, remaining conductive. Thus, the efficiency of the ion beam neutralization element 22 is maintained.

Moreover, in order to optimize particle fixing qualities of the collectors, the first and second included angles θ₁, θ₂ are between 45° and 70°, preferably 60°, with height (d) of the first and second protrusions about 1 cm.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An ion implantation apparatus, comprising:
an ion source;
a mass-analysis magnet for ion beam extracted from the ion source;
an accelerator accelerating or decelerating the ion beam; and
an ion implantation chamber including a work piece support moving one or more work pieces through the ion beam; and
a plurality of first collectors removably disposed on an interior surface of the ion implantation chamber, each comprising a first surface with a plurality of parallel saw-toothed first protrusions to fix contaminant particles in the ion implantation chamber.

2. The ion implantation apparatus as claimed in claim 1, further comprising:
a Faraday cup in the ion implantation chamber, disposed behind the work piece support in the emission direction of the ion beam to measure the current of the ion beam;
wherein the first collectors are mounted on the interior surface of the ion implantation chamber with the first surface facing the Faraday cup.

3. The ion implantation apparatus as claimed in claim 2, wherein first collectors are grounded.

4. The ion implantation apparatus as claimed in claim 4, further comprising:
a connecting housing between the accelerator and the ion implantation chamber, having an ion beam neutralization element and a plurality of second collectors, removably mounted on the interior surface of the housing, each comprising a second surface with a plurality of parallel saw-toothed second protrusions to fix contaminant particles in the housing.

5. The ion implantation apparatus as claimed in claim 4, wherein the second collectors are grounded, forming a bias voltage in the connecting housing with the ion beam neutralization element.

6. The ion implantation apparatus as claimed in claim 4, wherein each of the first protrusions has a first toothed surface and a second toothed surface with a first included angle, each of the second protrusions has a third toothed surface and a fourth toothed surface with a second included angle, and the first and second included angles are between 45 and 70°.

7. The ion implantation apparatus as claimed in claim 6, wherein the first toothed surface of each first protrusion is perpendicular to the first surface of each first collector.

8. The ion implantation apparatus as claimed in claim 6, wherein the third toothed surface of each second protrusion is perpendicular to the second surface of each second collector.

9. The ion implantation apparatus as claimed in claim 6, wherein the first and second collectors are graphite.

10. An ion implantation apparatus, comprising:
an ion source;
a mass-analysis magnet for an ion beam extracted from the ion source;
an accelerator accelerating or decelerating the ion beam; and
an ion implantation chamber including a work piece support moving one or more work pieces through the ion beam;
a connecting housing between the accelerator and the ion implantation chamber having an ion beam neutralization element;
a plurality of second collectors removably mounted on an interior surface of the housing, wherein each second collector has a second surface with a plurality of parallel saw-toothed second protrusions to fix contaminant particles in the housing.

11. The ion implantation apparatus as claimed in claim 10, wherein the second collectors are grounded, forming a bias voltage in the connecting housing with the ion beam neutralization element.

12. The ion implantation apparatus as claimed in claim 10, wherein each of the second protrusions has a third toothed surface and a fourth toothed surface with a second included angle, and the second included angle is between 45 and 70°.

13. The ion implantation apparatus as claimed in claim 12, wherein the third toothed surface of each second protrusion is perpendicular to the second surface of each second collector.

14. The ion implantation apparatus as claimed in claim 10, wherein the second collectors are graphite.
